(19) United States
(12) Patent Application Publication
(10) Pub. No.: US 2010/0238743 A1
(43) Pub. Date: Sep. 23, 2010

(54) FAST EMBEDDED BiCMOS-THYRISTOR LATCH-UP NONVOLATILE MEMORY

(76) Inventor: James Pan, West Jordan, UT (US)

Correspondence Address: James Pan, 655 Baker St., Apt. J210, Costa Mesa, CA, 92626, US

(21) Appl. No.: 12/408,721

(22) Filed: Mar. 23, 2009

(51) Int. Cl. G11C 7/00

(52) U.S. Cl. 365/189.011

(57) ABSTRACT

This disclosure describes a new semiconductor non-volatile memory that can be potentially faster than DRAM and FLASH, and the manufacturing cost can be lower than SRAM, which is volatile. It is possible to fabricate an ULSI microprocessor and this type of new memory array in the same chip—realizing the “embedded” process. There are a CMOS transistor and latched-up Bipolar transistors (A thyristor) in the device. The fast read, write and erase operations are done by charging the MOS gate capacitor interface and sensing the latch-up voltage of the thyristor. The latch-up voltage of the thyristor is reduced for the additional MOSFET current during the write process, causing early avalanche breakdown and the latch-up of the bipolar transistors. The semiconductor memory can be fabricated as a planar device or a vertical device.

### BACKGROUND OF THE INVENTION

Semiconductor memories are important for computing and communication in modern societies. There are a few different types of semiconductor memories in use today: DRAM (Dynamic Random Access Memory), SRAM (Static Random Access Memory) and FLASH (Nonvolatile). DRAM is a low manufacturing cost memory with only one transistor and storage capacitor in a cell. It is also very fast because electrons can move in and out of the storage cell quickly. But data can be lost in DRAM once the power is disconnected. SRAM is also a fast memory. The cost for SRAM is higher due to the 6 transistors in one cell. It is a volatile memory and the stored data will be lost if the power is turned off. FLASH is a common nonvolatile memory with one single transistor and potential multiple bits storage. But the FLASH memory is much slower compared to DRAM and SRAM, because the read and write operations need the so called “tunneling process” through a thin gate oxide. In this disclosure, a new type of fast nonvolatile memory is proposed. It is very small and fast—no tunneling is necessary. It is nonvolatile—the stored charges remain even after the power is turned off.

### BRIEF SUMMARY OF THE INVENTION

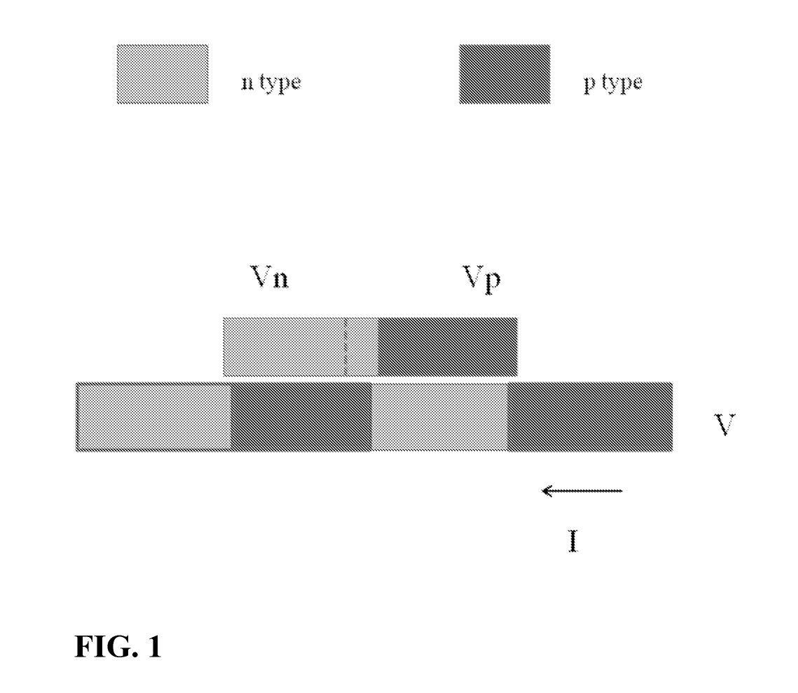

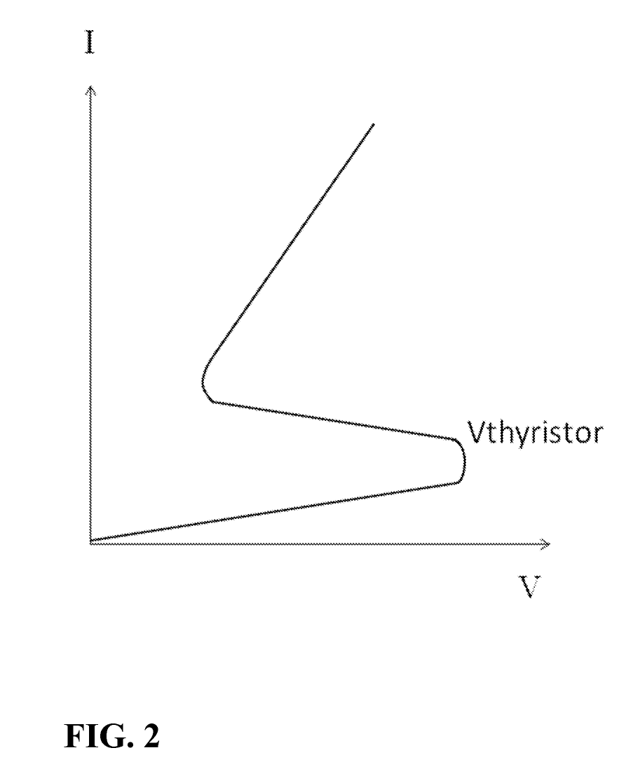

The storage cell (cross section—in FIG. 1) consists of two MOS transistors—a PMOS and a NMOS transistor. There are two bipolar transistors under the CMOS—these two transistors are “latched up” and function like a thyristor. The gate oxide is composed of a material with many interfacial states or traps. For the NMOS, if a negative gate voltage is applied, accumulation of positive charges in the silicon surface happens. If a positive gate voltage is applied, negative inversion charges show up in the silicon surface. When positive charges are trapped in the gate dielectrics/silicon interface, the Vthyristor (in FIG. 2) decreases. If negative charges are trapped at the interface, the Vthyristor increases. The same principle is applied to the PMOS, with the polarity of the charges reversed. So the “WRITE” operation is to apply a negative voltage to the NMOS gate and a positive voltage to the PMOS gate, or vice versa, causing Vthyristor to be low or high, respectively. The “READ” operation is non-destructive by sensing the Vthyristor. The “ERASE” operation is to apply a positive voltage to the NMOS gate and a negative voltage to the PMOS gate, or vice versa, causing the Vthyristor to be high or low. The gate oxide for the CMOS transistors is specially designed with many dangling silicon bonds and traps. One way to accomplish this is to incorporate carbon during the oxidation process.

### DETAILED DESCRIPTION OF THE INVENTION FIGURE CAPTIONS

In FIG. 1, the wells of the CMOS transistors are specially designed to control the thyristor breakdown voltage (Vthyristor). The p and n well are narrow by keeping the sources (in between the two gates) short, so once the “WRITE” operation is done the Vthyristor can be effectively increased. When a positive voltage is applied to the p type region on the right side, the p-n junction formed in between the two wells is reversed biased, causing Vthyristor to be high. But the Vthyristor can be adjusted by applying voltages to the CMOS gate—this is the READ and WRITE operations.

In FIG. 2, the Thyristor I-V is shown. If the p-n junction in between the two wells are reversed biased, the Vthyristor is high. If that p-n junction is forward biased, the two bipolar transistors are in saturation (low gate mode) and latched up, causing the Vthyristor to be low.

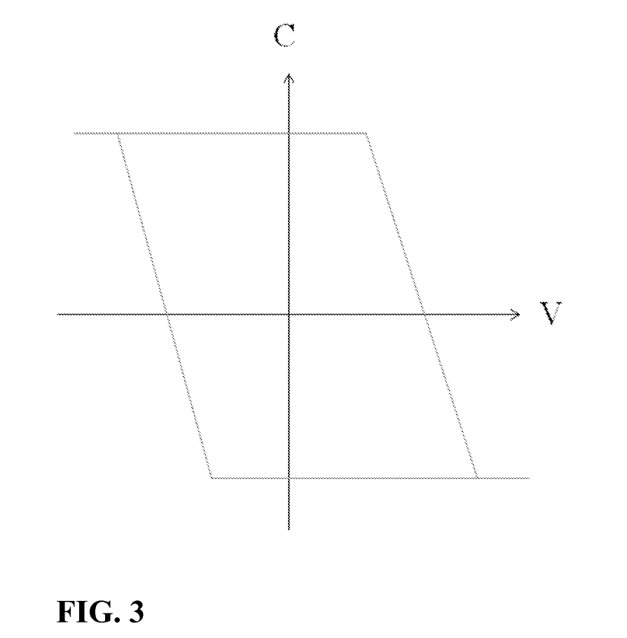

FIG. 3. If the gate oxide/silicon interface is full of traps, the C-V curve would look like a hysteresis. The NMOS CV is shown in FIG. 3. A PMOS CV would be reversed in polarity. The “WRITE” for the NMOS is to apply a negative gate voltage, so the resulted capacitance at 0 V is low. The “ERASE” operation is to apply a positive gate voltage, so the resulted capacitance at 0 V is high. The “READ” operation is to sense the thyristor breakdown voltage—Vthyristor.

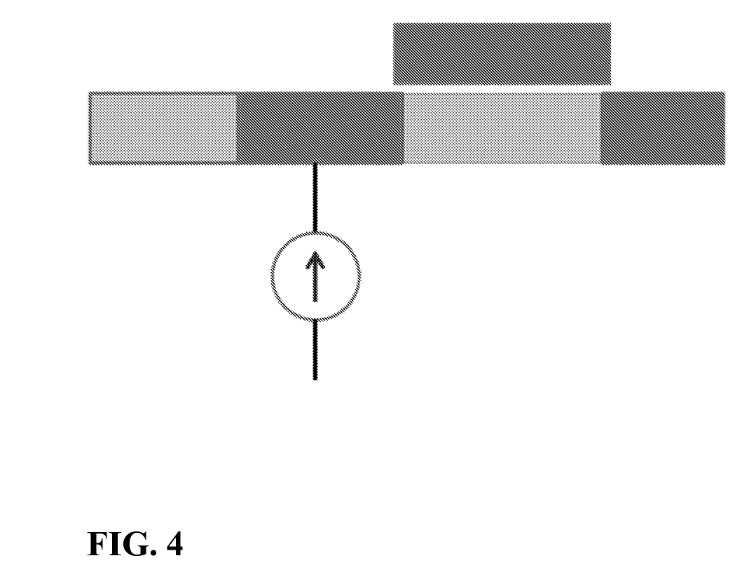

FIG. 4 shows the simplified storage unit -with only one MOS gate. The “READ” is done by forcing a current to the base of the bipolar transistor and sense the collector voltage. The “WRITE” operation is to apply a positive voltage to the gate. The “ERASE” is done by applying a negative voltage to the gate.

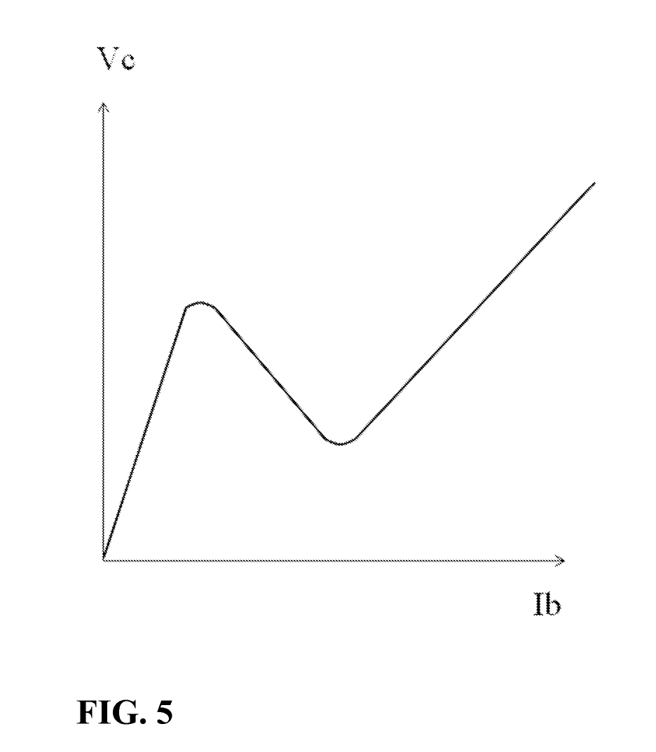

FIG. 5 shows the collector voltage vs. the base current plot. The peak collector voltage vanishes if there is positive charges trapped at the gate oxide/silicon interface.

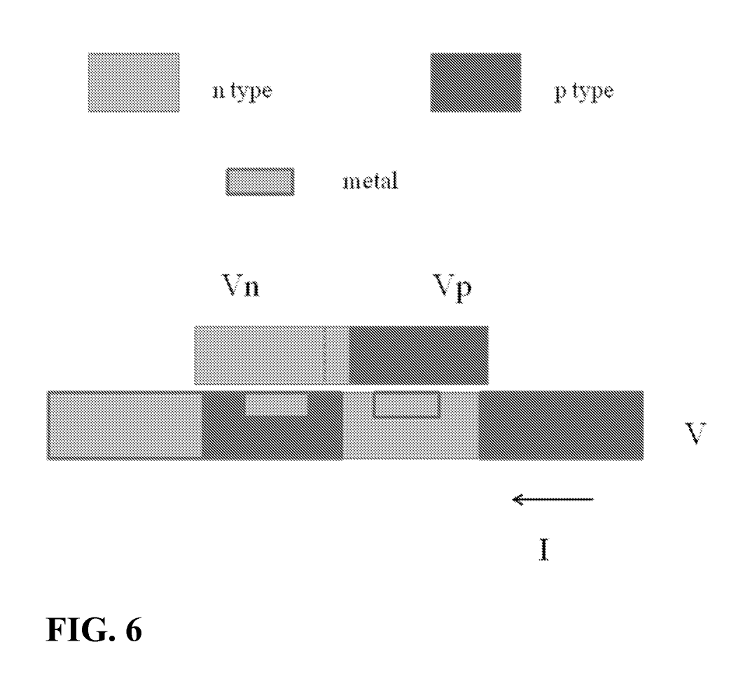

FIG. 6 shows a metal region in the silicon channel for the CMOS transistors. This piece of metal, or metal silicide, can adjust the threshold voltage of the MOS transistors through the so called “body effect”, when the metal/SiO₂ interface is charged.

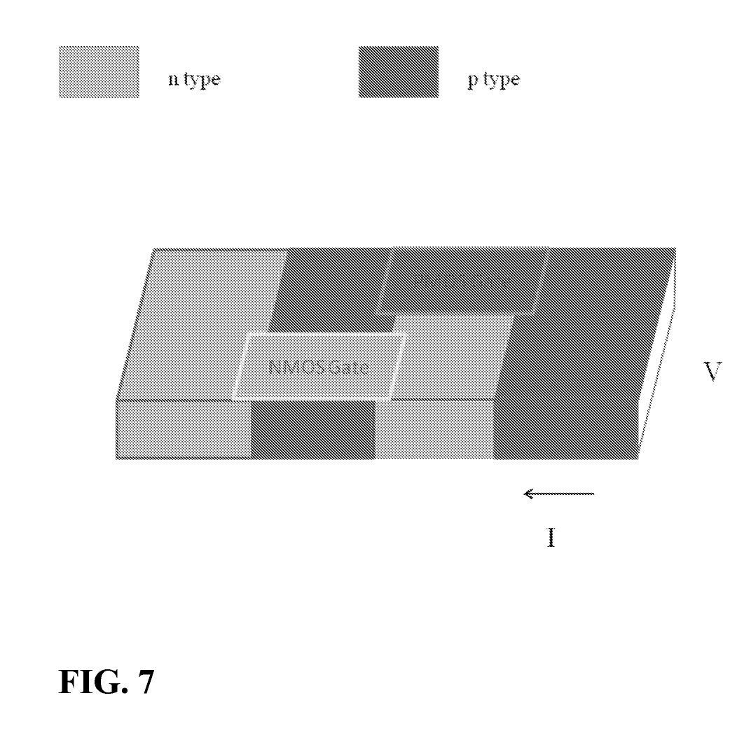

FIG. 7 shows the top down view of the device. The NMOS and PMOS gates can be designed by special layouts to cover the n and p regions in the center alternatively.

What is claimed is:

1. The memory function consists of CMOS, Bipolar and Thyristor operations. The CMOS gate oxide is designed to have many traps for charges. A metal region can be fabricated in the silicon channel to enhance the charging effects. The “WRITE” operation is to force opposite voltages to the CMOS gates. The “READ” operation is to sense the thyristor breakdown voltage. The “ERASE” operation is to apply voltages to the CMOS gate to change the polarity of trapped charges at the interface. The bipolar transistors are designed to function efficiently as a latched-up thyristor. The storage can also by simplified by using only one MOS gate. The “READ” is done differently, but sensing the collector voltage while forcing a base current to the bipolar transistor.
